(19) United States
(12) Patent Application Publication
(10) Pub. No.: US 2023/0350438 A1
(43) Pub. Date: Nov. 2, 2023

(54) PROCESS MEASUREMENT APPARATUS AND METHOD

(71) Applicant: SEMES Co., Ltd., Chungcheongnam-do (KR)

(72) Inventors: Yong Jun Seo, Gyeonggi-do (KR); Sang Hyun Son, Busan (KR); Sang Min Ha, Gyeonggi-do (KR); Hyeong Jun Cho, Seoul (KR); Dong Ok Ahn, Gyeonggi-do (KR)

(21) Appl. No.: 17/732,553

(22) Filed: Apr. 29, 2022

(51) Int. Cl. H01L 21/67; G05D 23/19; G01K 3/14

(52) U.S. Cl. CPC G05D 23/1927; G01K 3/14; H01L 21/67248; H01L 21/67103

(57) ABSTRACT

A process measurement apparatus and method capable of increasing production by decreasing an operating time are provided. The process measurement method is performed by a computing device, and includes receiving a plurality of sensed values from a plurality of sensors disposed in a wafer-type temperature sensor, generating a first temperature value of a first heating zone based on the plurality of sensed values, and determining a first compensation value based on a first difference value corresponding to a difference between the first temperature value and a target value, wherein a first compensation ratio between the first difference value and the first compensation value when the first difference value is a first value is different from a second compensation ratio between the first difference value and the first compensation value when the first difference value is a second value.

### BACKGROUND

### 1. Technical Field

The present disclosure relates to a process measurement apparatus and method.

### 2. Description of the Related Art

When a semiconductor device or a display device is manufactured, various processes such as photographing, etching, ion implantation, thin film deposition, and cleaning are performed. A wafer-type temperature sensor may be used in order to measure a process environment and condition. The wafer-type temperature sensor includes a plurality of sensors installed on a body having a wafer shape. A temperature distribution actually applied to a wafer may be measured/predicted by introducing the wafer-type temperature sensor into a process equipment and measuring a temperature distribution within the process equipment.

### SUMMARY

A conventional process measurement method using the wafer-type temperature sensor is as follows. The wafer-type temperature sensor is introduced into a bake unit, and a temperature distribution within the bake unit is measured. The wafer-type temperature sensor is moved from the bake unit to a dedicated data output device to output data (i.e., a measured temperature distribution). An operator confirms the output data and determines an offset of the bake unit. The determined offset is reflected, the wafer-type temperature sensor is introduced again into the bake unit, and the temperature distribution within the bake unit is re-measured. The operator repeats the above operations until the temperature distribution in the bake unit coincides with a desired temperature distribution. In particular, the operator has arbitrarily calculated the offset or has determined the offset based on experience, and thus, there was inevitably a difference in operating time depending on a skill of the operator.

Aspects of the present disclosure provide a process measurement apparatus and method capable of increasing production by decreasing an operating time.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

An aspect of a process measurement method performed by a computing device comprising, receiving a plurality of sensed values from a plurality of sensors disposed in a wafer-type temperature sensor, generating a first temperature value of a first heating zone based on the plurality of sensed values and determining a first compensation value based on a first difference value corresponding to a difference between the first temperature value and a target value, wherein a first compensation ratio between the first difference value and the first compensation value when the first difference value is a first value is different from a second compensation ratio between the first difference value and the first compensation value when the first difference value is a second value.

Another aspect of a process measurement method performed by a computing device comprising, receiving a plurality of sensed values from a plurality of sensors disposed in a wafer-type temperature sensor, generating a first temperature value of a first heating zone and a second temperature value of a second heating zone adjacent to the first heating zone based on the plurality of sensed values, determining a first compensation value based on a first difference value corresponding to a difference between the first temperature value and a target value; and determining a second compensation value based on a second difference value corresponding to a difference between the second temperature value and the target value and the first compensation value.

Still another aspect of a process measurement method performed by a computing device comprising, receiving a plurality of sensed values from a plurality of sensors disposed in a wafer-type temperature sensor, estimating a temperature gradation based on the plurality of sensed values, overlapping and displaying the estimated temperature gradation with a plurality of heating zones, and calculating and displaying temperature values of each of the plurality of heating zones based on the plurality of sensed values.

Detailed contents of other exemplary embodiments are described in a detailed description and are illustrated in the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating an illustrating substrate treating apparatus to which a process measurement method according to some exemplary embodiments of the present disclosure is applied;

FIG. 2A is a plan view for describing a heater installed in a substrate support unit of FIG. 1;

FIG. 2B is a view for describing an illustrative configuration of a heating zone (e.g., Z6) of FIG. 2A;

FIG. 3 is a block diagram for describing a process measurement module of FIG. 1;

FIG. 4 is a flowchart for describing a process measurement method according to some exemplary embodiments of the present disclosure;

FIG. 5 is a flowchart for describing an example of S320 (analyzing of a temperature distribution and determining of a compensation value) of FIG. 4;

FIG. 6 is a view for describing a relationship between sensors of a wafer-type temperature sensor and heating zones of a substrate treating apparatus;

FIG. 7 is a view for describing S326 of FIG. 5;

FIG. 8 is a flowchart for describing another example of S320 (analyzing of a temperature distribution and determining of a compensation value) of FIG. 4;

FIG. 9 is a graphical user interface (GUI) for describing software used in the process measurement method according to some exemplary embodiments of the present disclosure;

FIG. 10 is a view for describing a temperature distribution viewer of FIG. 9; and

FIG. 11 is a view for describing a data table of FIG. 9.

### DETAILED DESCRIPTION OF THE EMBODIMENTS

Hereinafter, exemplary embodiments of the present disclosure will be described in detail with reference to the accompanying drawings. Advantages and features of the present disclosure and a method of achieving these advantages and features will become apparent with reference to exemplary embodiments to be described later in detail in conjunction with the accompanying drawings. However, the present disclosure is not limited to exemplary embodiments to be disclosed below, but may be implemented in various different forms, these exemplary embodiments will be provided only in order to make the present disclosure complete and allow one of ordinary skill in the art to completely recognize the scope of the present disclosure, and the present disclosure will be defined by the scope of the claims. Throughout the specification, the same components will be denoted by the same reference numerals.

The spatially relative terms ‘below’, ‘beneath’, ‘lower’, ‘above’, ‘upper’, and the like, may be used in order to easily describe correlations between one element or component and other elements or components as illustrated in the drawings. The spatially relative terms are to be understood as terms including different directions of elements at the time of being used or at the time of operating in addition to directions illustrated in the drawings. For example, when elements illustrated in the drawings are overturned, an element described as ‘below or beneath’ another element may be put ‘above’ another element. Accordingly, an illustrative term “below” may include both of directions of above and below. Elements may be oriented in other directions as well, and accordingly, spatially relative terms may be interpreted according to orientations.

The terms ‘first’, ‘second’, and the like are used to describe various elements, components, and/or sections, but these elements, components, and/or sections are not limited by these terms. These terms are used only in order to distinguish one element, component, or section from another element, component or section. Accordingly, a first element, a first component, or a first section to be mentioned below may also be a second element, a second component, or a second section within the technical spirit of the present disclosure.

The terms used herein are for describing exemplary embodiments rather than limiting the present disclosure. In the present specification, a singular form includes a plural form unless stated otherwise in the phrase. Components, steps, operations, and/or elements mentioned by the terms “comprise” and/or “comprising” used herein do not exclude the existence or addition of one or more other components, steps, operations, and/or elements.

Unless defined otherwise, all the terms (including technical and scientific terms) used herein have the same meaning as meanings commonly understood by one of ordinary skill in the art to which the present disclosure pertains. In addition, the terms defined in generally used dictionaries are not ideally or excessively interpreted unless they are specifically defined clearly.

Hereinafter, exemplary embodiments of the present disclosure will be described in detail with reference to the accompanying drawings. In describing exemplary embodiments of the present disclosure with reference to the accompanying drawings, components that are the same as or correspond to each other will be denoted by the same reference numerals, and an overlapping description thereof will be omitted.

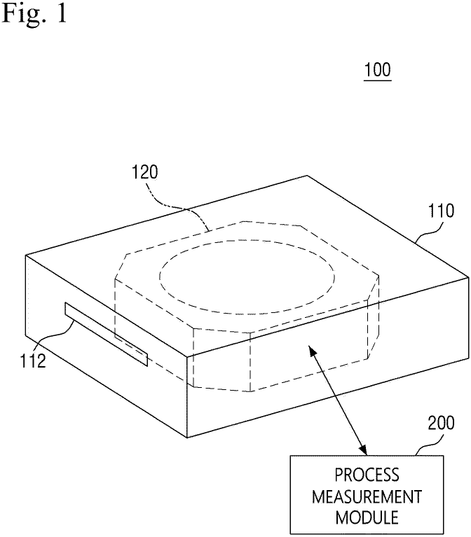

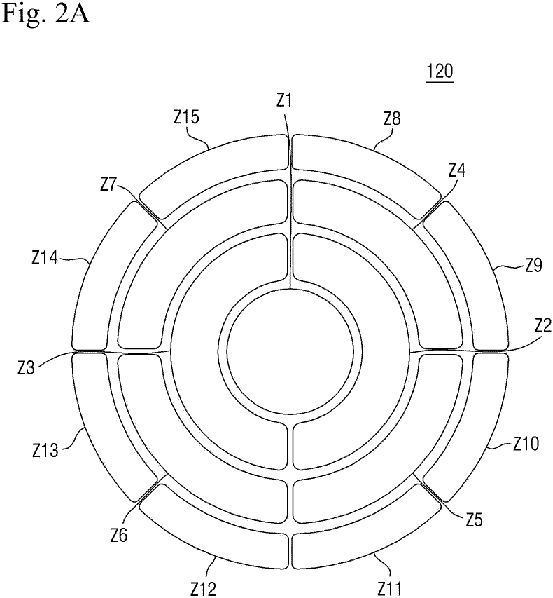

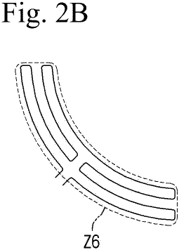

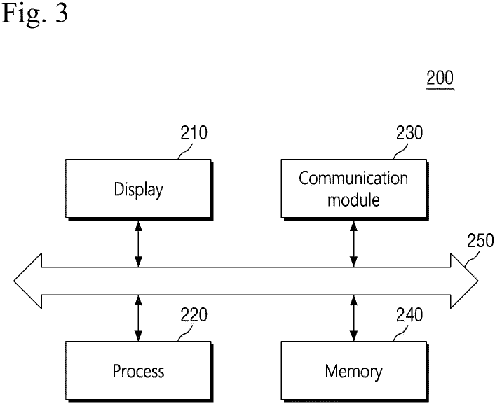

FIG. 1 is a view illustrating an illustrating substrate treating apparatus to which a process measurement method according to some exemplary embodiments of the present disclosure is applied. FIG. 2A is a plan view for describing a heater installed in a substrate support unit of FIG. 1, and FIG. 2B is a view for describing an illustrative configuration of a heating zone (e.g., Z6) of FIG. 2A. FIG. 3 is a block diagram for describing a process measurement module of FIG. 1.

First, in FIG. 1, a bake unit is illustrated as an example of a substrate treating apparatus 100. The bake unit is an equipment for heat-treating a substrate to a process temperature or higher, and may heat an entire area of the substrate to a uniform temperature or adjust a temperature for each area of the substrate according to an operator.

The substrate treating apparatus 100 may include a chamber 110, an entrance 112, a substrate support unit 120, and the like.

The chamber 110 provides a space for heat-treating the substrate therein. During a baking process, an inner portion of the chamber 110 may be in a normal pressure or reduced pressure atmosphere. The entrance 112 may be installed at one side of the chamber 110, and a wafer on which the baking process is to be performed may be inserted into the chamber or a wafer on which the baking process has been completed may be taken out from the chamber, through the entrance 112. Although not illustrated separately, a peripheral hole for introducing an airflow (e.g., an inert gas or air) into the chamber 110 may be formed in a sidewall of the chamber 110.

The substrate support unit 120 is disposed in the chamber 110, and the wafer is seated and heat-treated on an upper surface of the substrate support unit 120.

The substrate support unit 120 may be divided into a plurality of heating zones Z1 to Z15, as illustrated in FIG. 2A, and at least one heating member is installed in each of the heating zones Z1 to Z15. The heating member may be, for example, a thermoelectric element or a heating wire. The plurality of heating zones Z1 to Z15 are positioned on the same plane of the substrate support unit 120. In addition, temperatures of the plurality of heating zones Z1 to Z15 may be independently adjusted. As illustrated in FIG. 2B, heating wires may be arranged/disposed in a predetermined manner within the heating zone (e.g., Z6).

For example, the heating zone Z1 is positioned at the most center of the substrate support unit 120, and two heating zones Z2 and Z3 are positioned to surround the heating zone Z1. In addition, four heating zones Z4, Z5, Z6, and Z7 are positioned to surround the two heating zones Z2 and Z3. Here, two heating zones (e.g., Z4 and Z5) may be positioned in each heating zone (e.g., Z2). In addition, eight heating zones Z8 to Z15 are positioned to surround the four heating zones Z4, Z5, Z6, and Z7. Here, two heating zones (e.g., Z8 and Z9) may be positioned in each heating zone (e.g., Z4).

It has been described by way of example in FIG. 2A that the heating zones Z1 to Z15 are disposed four-fold (i.e., Z1, Z2 to Z3, Z4 to Z7, Z8 to Z15), but the present disclosure is not limited thereto. That is, the heating zones may be arranged three-fold or five-fold. In addition, it has been described in FIG. 2A that the number of heating zones (e.g., Z8 and Z9) corresponding to the outside of each heating zone (e.g., Z4) is two, but the present disclosure is not limited thereto. That is, the number of heating zones corresponding to the outside of each heating zone may also be three or more.

It has been illustrated that the number of heating zones Z1 to Z15 divided from the substrate support unit is 15, but the present disclosure is not limited thereto. For example, the number of heating zones may also be 16 or more.

In addition, although not illustrated separately, a plurality of pin holes may be installed in a seating surface (surface that the substrate is in contact with) of the substrate support unit 120, and lift pins movable in a vertical direction may be provided in the pin holes. The lift pins lift the substrate or seat the substrate on the seating surface of the substrate support unit 120.

Meanwhile, the substrate treating apparatus 100 is not limited to the bake unit, and may be any apparatus that needs to measure a temperature distribution using a wafer-type temperature sensor.

In addition, according to an exemplary embodiment, a cooling plate cooling the wafer in the bake unit may be further installed. The cooling plate may include a cooling means such as a coolant or a thermoelectric element installed therein to cool the wafer to a temperature equal to or close to room temperature.

The substrate treating apparatus 100 may be connected to a process measurement module 200. Here, referring to FIG. 3, the process measurement module 200 is a computing device, and may include a display 210, a processor 220, a communication module 230, a memory 240, a bus 250, an input/output interface, and the like.

Various components such as the display 210, the processor 220, the communication module 230, and the memory 240 may be connect to and communicate with each other (i.e., transfer control messages and transfer data), by the bus 250.

The processor 220 may include one or more of a central processing unit, an application processor, and a communication processor (CP). The processor 220 may, for example, execute an operation or data processing related to control and/or communication of at least one other component of the computing device.

The display 210 may include, for example, a liquid crystal display (LCD), a light emitting diode (LED) display, an organic light emitting diode (OLED) display, or a micro-electro mechanical system (MEMS) display, or an electronic paper display. The display 210 may display, for example, various contents (e.g., a text, an image, a video, an icon, and/or a symbol, etc.) to a user. The display 210 may include a touch screen, and may receive, for example, a touch, gesture, approach, or hovering input using an electronic pen or a portion of a user’s body.

The memory 240 may include a volatile memory (e.g., a dynamic random access memory (DRAM), a static random access memory (SRAM), or a synchronous dynamic random access memory (SDRAM) and/or a non-volatile memory (e.g., a one time programmable read only memory (OTPROM), a programmable read only memory (PROM), an erasable programmable read only memory (EPROM), an electrically erasable programmable read only memory (EEPROM), a mask ROM, a flash ROM, a flash memory, a phase-change RAM (PRAM), a resistive RAM (RRAM), a magnetic RAM (MRAM), a hard drive, or a solid state drive (SSD)). The memory 240 may include an internal memory and/or an external memory. The memory 240 may store commands or data related to at least one other component of the computing device. In addition, the memory 240 may store software and/or a program.

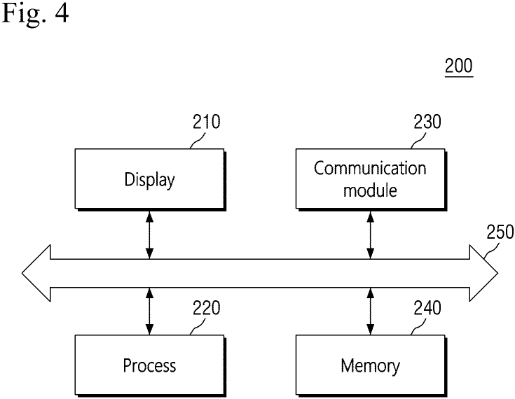

The memory 240 stores instructions for performing a process measurement method to be described with reference to FIGS. 4 to 11.

For example, the memory 240 includes instructions for receiving a plurality of sensed values from a plurality of sensors disposed in a wafer-type temperature sensor, generating a first temperature value of a first heating zone based on the plurality of sensed values, and determining a first compensation value based on a first difference value corresponding to a difference between the first temperature value and a target value. Here, a first compensation ratio between the first difference value and the first compensation value when the first difference value is a first value is controlled to be different from a second compensation ratio between the first difference value and the first compensation value when the first difference value is a second value.

Alternatively, the memory 240 may include instructions for receiving a plurality of sensed values from a plurality of sensors disposed in the wafer-type temperature sensor, generating a first temperature value of a first heating zone and a second temperature value of a second heating zone adjacent to the first heating zone based on the plurality of sensed values, determining a first compensation value based on a first difference value corresponding to a difference between the first temperature value and a target value, and determining a second compensation value based on a second difference value corresponding to a difference between the second temperature value and the target value and the first compensation value.

Alternatively, the memory 240 may include instructions for receiving a plurality of sensed values from a plurality of sensors disposed in the wafer-type temperature sensor, estimating a temperature gradation based on the plurality of sensed values, overlapping and displaying the estimated temperature gradation with the plurality of heating zones, and calculating and displaying temperature values of each of the plurality of heating zones based on the plurality of sensed values.

In addition, the communication module 230 may communicate with the substrate treating apparatus 100 in a wired and/or wireless manner. Wireless communication may include, for example, cellular communication that uses at least one of long term evolution (LTE), LTE Advance (LTE-A), code division multiple access (CDMA), wideband CDMA (WCDMA), a universal mobile telecommunications system (UMTS), wireless broadband (WiBro), or a global system for mobile communications (GSM). Alternatively, the wireless communication may include at least one of wireless fidelity (WiFi), light fidelity (LiFi), Bluetooth, Bluetooth low power (BLE), Zigbee, near field communication (NFC), magnetic secure transmission, a radio frequency (RF), or a body area network (BAN). Alternatively, the wireless communication may include a global navigation satellite system (GNSS). The GNSS may be, for example, a global positioning system (GPS), a global navigation satellite system (Glonass), a Beidou navigation satellite system (hereinafter, referred to as “Beidou”) or Galileo, that is, European global satellite-based navigation system. Wired communication may include, for example, at least one of a universal serial bus (USB), a high definition multimedia interface (HDMI), recommended standard 232 (RS-232), power line communication, a plain old telephone service (POTS), a computer network (e.g., a local area network (LAN) or a wide area network (WAN), or the like.

FIG. 4 is a flowchart for describing a process measurement method according to some exemplary embodiments of the present disclosure.

Referring to FIG. 4, the wafer-type temperature sensor is conveyed into the substrate treating apparatus 100 (see FIG. 1) (S310).

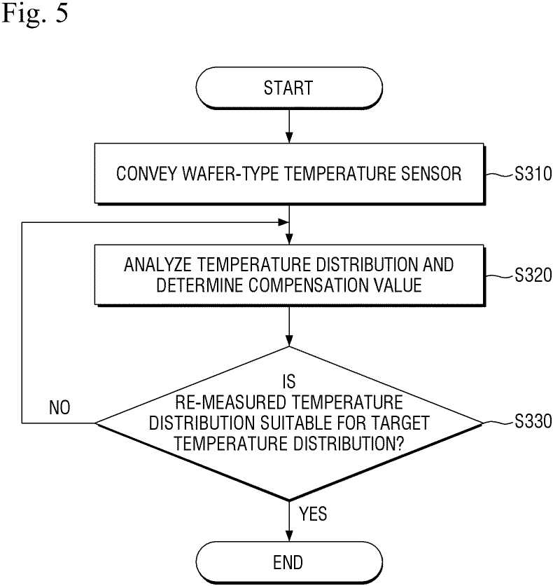

Next, a temperature distribution in the substrate treating apparatus 100 is measured using the wafer-type temperature sensor. In addition, in a state in which the wafer-type temperature sensor is introduced into the substrate treating apparatus 100 (that is, without moving the wafer-type temperature sensor to a separate dedicated data output device), the temperature distribution in the substrate treating apparatus 100 is analyzed, and a compensation value is determined (S320). A method of analyzing the temperature distribution and determining the compensation value will be described later in detail with reference to FIGS. 5 to 8.

Next, after the determined compensation value is reflected, the temperature distribution in the substrate treating apparatus 100 is re-measured using the wafer-type temperature sensor. It is checked whether or not the re-measured temperature distribution is suitable for a target temperature distribution (S330). When the re-measured temperature distribution is not suitable for the target temperature distribution, the process measurement method returns to S320. When the re-measured temperature distribution is suitable for the target temperature distribution, the process measurement method ends.

As described above, the process measurement module 200 and the substrate treating apparatus 100 may exchange data with each other in a state in which they are connected to each other in a wired and/or wireless manner. There is no need to move the wafer-type temperature sensor from the substrate treating apparatus 100 to the dedicated data output device and read the temperature distribution measured by the wafer-type temperature sensor. That is, in a state in which the wafer-type temperature sensor is positioned in the substrate treating apparatus 100, the analyzing of the temperature distribution and the determining of the compensation value (S320) and the re-measuring of the temperature distribution after the compensation value is reflected and the checking of whether or not the re-measured temperature distribution is suitable for the target temperature distribution (S330) are continuously performed.

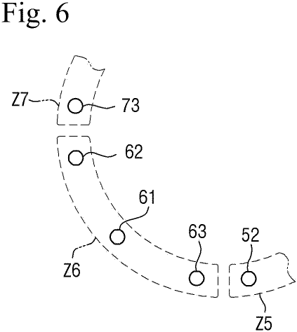

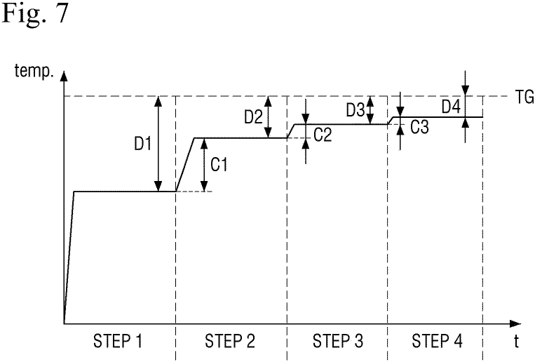

FIG. 5 is a flowchart for describing an example of S320 (analyzing of a temperature distribution and determining of a compensation value) of FIG. 4. FIG. 6 is a view for describing a relationship between sensors of a wafer-type temperature sensor and heating zones of a substrate treating apparatus. FIG. 7 is a view for describing S326 of FIG. 5.

First, referring to FIG. 5, a plurality of sensed values are received from a plurality of sensors disposed in the wafer-type temperature sensor (S322).

Specifically, as illustrated in FIG. 6, the plurality of sensors (e.g., 61, 62, 63, 52, and 73) disposed in the wafer-type temperature sensor correspond to a plurality of heating zones Z5, Z6, and Z7. For example, some sensors 61, 62, and 63 may correspond to the heating zone Z6, another sensor 52 may corresponds to another heating zone Z5, and still another sensor 73 may correspond to still another heating zone Z7. It has been illustrated in FIG. 6 that three sensors 61, 62, and 63 correspond to one heating zone (e.g., Z6) for convenience of explanation, but the present disclosure is not limited thereto.

The process measurement module 200 may receive sensed values measured by such sensors (e.g., 61, 62, 63, 52, and 73) in a wired and/or wireless manner. In a state in which the wafer-type temperature sensor is positioned in the substrate treating apparatus 100, the process measurement module 200 may receive the sensed values.

The process measurement module 200 may receive the sensed values in real time. For example, the process measurement module 200 may continually or continuously receive the sensed values. For example, the process measurement module 200 may continually receive the sensed values 60 times for three minutes.

Next, a first temperature value of a first heating zone (e.g., Z6 in FIG. 6) is generated based on the plurality of sensed values that are received (S324).

Specifically, the generating of the first temperature value may be performed after standard deviations of the plurality of sensed values received for preset periods are maintained below a preset value.

The sensed values are continually received, and standard deviations of the received sensed values are calculated. Here, when the standard deviations are maintained below the preset value for preset periods (e.g., 60 sampling periods), it is decided as a stable condition. A standard deviation of a plurality of sensed values received at the time of x-th sampling is referred to as an “x-th standard deviation”. For example, a first standard deviation may be 0.3, a second standard deviation may be 0.25, and a twenty standard deviation may be 0.03. A twenty first standard deviation may fall below 0.03. When all of the twenty first standard deviation to an eightieth standard deviation are maintained below 0.03 (that is, when the standard deviations are maintained below 0.03 for 60 sampling periods), it may be decided as the stable condition. In the stable condition, the first temperature value is generated.

For example, the wafer-type temperature sensor may include a first sensor 61 (see FIG. 6) and second sensors 62 and 63 (see FIG. 6) corresponding to the first heating zone (e.g., Z6 in FIG. 6) and the second sensors 62 and 63 may be disposed outside the first sensor 61 in the first heating zone Z6.

The first temperature value of the first heating zone Z6 may be generated based on a first sensed value of the first sensor 61 and second sensed values of the second sensors 62 and 63.

For example, the first temperature value may be a weighted average of the first sensed value and the second sensed values, and a first weight given to the first sensed value may be greater than a second weight given to the second sensed values. In addition, the second weight given to the second sensed values may be affected by a second temperature value of a second heating zone (e.g., Z5) adjacent to the first heating zone Z6.

The first sensor 61 positioned at a central portion of the first heating zone Z6 is less affected by the surrounding heating zones (e.g., Z5 and Z7) than the other sensors 62 and 63 of the first heating zone Z6 are. In addition, since the first temperature value is a representative value representing the first heating zone Z6, a large weight may be given to the first sensed value of the first sensor 61.

On the other hand, the second sensors 62 and 63 disposed at an outer portion of the first heating zone Z6 are affected not only by the first heating zone Z6 itself, but also by the surrounding heating zones (e.g., Z5 and Z7). Accordingly, when a temperature of the surrounding heating zone (e.g., Z5) is high, the second sensed value of the second sensor (e.g., 62) may also increase. Accordingly, the second weight given to the second sensed value is affected by the temperature value of the surrounding heating zone.

Next, a first compensation value is determined based on a first difference value corresponding to a difference between the first temperature value and a target value (S326).

Specifically, the first difference value corresponding to the difference between the first temperature value and the target value TG is calculated. For example, when the first temperature value is 100° C. and the target value TG is 110° C., the first difference value is 10° C.

The first compensation value may be determined based on the first difference value (i.e., 10° C.).

Here, the compensation value may be a parameter value adjusted for each of the heating zones Z1 to Z15 for independent heat-treatment in each of the heating zones Z1 to Z15. For example, when a temperature of each of the heating zones Z1 to Z15 is adjusted by adjusting an amount of current provided to each of the heating zones Z1 to Z15, the compensation value may be a change amount in the amount of current. For example, a current amount of current of a certain heating zone may be 1 A, and the compensation value may be 0.1 A. In this case, the amount of current of the heating zone may be changed to 1.1 A.

Meanwhile, in some exemplary embodiments of the present disclosure, the first compensation value may be determined as a value compensated to be smaller than the first difference value. For example, even though the first difference value is 10° C. and a compensation value generally known (or calculated by a calculation equation) to increase the temperature of the heating zone by 10° C. is 0.2 A, the first compensation value may be determined as 0.1 A rather than 0.2 A.

Since the substrate support unit 120 includes the plurality of heating zones Z1 to Z15 adjacent to each other, the temperature of each of the heating zones Z1 to Z15 is not determined only by the amount of current provided to each of the heating zones Z1 to Z15, and is significantly affected by temperatures of the surrounding heating zones Z1 to Z15. Because of the affection of these surrounding heating zones Z1 to Z15, when the compensation value is determined to be 0.2 A in order to increase the temperature of the heating zone by 10° C., the temperature of the heating zone may be increased by 15° C. rather than 10° C. Accordingly, in the process measurement method according to some exemplary embodiments of the present disclosure, the first compensation value may be determined as a value compensated to be smaller than the first difference value (e.g., 10° C.) (e.g., a value that may increase the temperature of the heating zone by 5° C.).

Next, after the determined first compensation value is reflected, the first temperature value of the first heating zone Z6 is re-generated using the wafer-type temperature sensor. When the re-generated first temperature value is not suitable for the target value, the first compensation value is re-calculated, and the re-calculated first compensation value is reflected. Such processes are repeated.

Here, a method of determining a compensation value will be described in more detail with reference to FIG. 7. In FIG. 7, an x-axis indicates a time, and a y-axis indicates a temperature value of the heating zone (e.g., Z6). Each of STEP1 to STEP4 refers to a tuning step.

In a first tuning step STEP1, a difference value D1 corresponding to a difference between a temperature value of the heating zone Z6 and a target value TG is calculated. A compensation value C1 is determined as a value compensated to be smaller than the difference value D1.

In a second tuning step STEP2, a difference value D2 corresponding to a difference between a temperature value of the heating zone Z6 changed after reflecting the compensation value C1 and the target value TG is calculated. The temperature value of the heating zone Z6 changed after reflecting the compensation value C1 may be affected by the surrounding heating zones Z5 and Z7. That is, the temperature value of the heating zone Z6 changed after reflecting the compensation value C1 may be higher or lower than that illustrated in FIG. 7. A compensation value C2 is determined as a value compensated to be smaller than the difference value D2.

In a third tuning step STEP3, a difference value D3 corresponding to a difference between a temperature value of the heating zone Z6 changed after reflecting the compensation value C2 and the target value TG is calculated. The temperature value of the heating zone Z6 changed after reflecting the compensation value C2 may be affected by the surrounding heating zones Z5 and Z7. That is, the temperature value of the heating zone Z6 changed after reflecting the compensation value C2 may be higher or lower than that illustrated in FIG. 7. A compensation value C3 is determined as a value compensated to be smaller than the difference value D3.

In a fourth tuning step STEP4, a difference value D4 corresponding to a difference between a temperature value of the heating zone Z6 changed after reflecting the compensation value C3 and the target value TG is calculated. The temperature value of the heating zone Z6 changed after reflecting the compensation value C3 may be affected by the surrounding heating zones Z5 and Z7. That is, the temperature value of the heating zone Z6 changed after reflecting the compensation value C3 may be higher or lower than that illustrated in FIG. 7. A compensation value is determined as a value compensated to be smaller than the difference value D4.

Meanwhile, a compensation ratio (= C1/D1) between the difference value D1 and the compensation value C1 in STEP1 may be, for example, 50%, a compensation ratio (= C2/D2) between the difference value D2 and the compensation value C2 in STEP2 may be, for example, for example, 30%, and a compensation ratio (= C3/D3) between the difference value D3 and the compensation value C3 in STEP3 may be, for example, 20%. That is, the compensation ratios may be changed depending on how much the difference values D1, D2, and D3 are. For example, the greater the difference values D1, D2, and D3, the higher the compensation ratios, and the smaller the difference values D1, D2, and D3, the lower the compensation ratios.

By changing the compensation ratios (C1/D1, C2/D2, and C3/D3) depending on the difference values D1, D2, and D3 as described above, the temperature value is adjusted to more carefully approach the target value. When the compensation ratios (C1/D1, C2/D2, and C3/D3) are adjusted as described above, the number of times of tuning (STEP1 to STEP4) may be increased, but more precise tuning is possible.

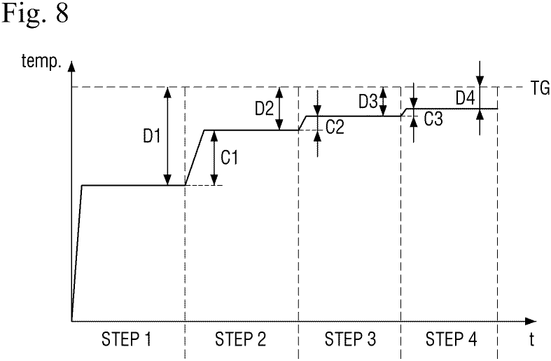

FIG. 8 is a flowchart for describing another example of S320 (analyzing of a temperature distribution and determining of a compensation value) of FIG. 4. For convenience of explanation, contents different from those described with reference to FIGS. 4 to 7 will be mainly described.

Referring to FIG. 8, a plurality of sensed values are received from a plurality of sensors disposed in the wafer-type temperature sensor (S322).

Next, a first temperature value of a first heating zone (e.g., Z6 in FIG. 6) and a second temperature value of a second heating zone (e.g., Z5 in FIG. 6) adjacent to the first heating zone are generated based on the plurality of sensed values (S325).

As described above, the generating of the first temperature value and the second temperature value may be performed after standard deviations of the plurality of sensed values received for preset periods are maintained below a preset value.

As described above, the first temperature value and the second temperature value may be generated based on the sensed values of the plurality of sensors corresponding to the respective heating zones. A weight of the sensed value of the sensor positioned at a central portion of each heating zone may be set to be high, and a weight of the sensed values of the sensors positioned at an outer portion of each heating zone may be changed depending on the affection of the surrounding heating zones.

Next, a first compensation value is determined based on a first difference value corresponding to a difference between the first temperature value and a target value (S327). Next, a second compensation value is determined based on a second difference value corresponding to a difference between the second temperature value and the target value and the first compensation value (S329).

Specifically, the first difference value is greater than the second difference value. Since the first difference value is greater than the second difference value, the first compensation value is determined before the second compensation value (without considering the second compensation value), and when the second compensation value is determined, the second compensation value is determined in consideration of the first compensation value. That is, the first compensation value is not affected by the second compensation value.

As described above, when the first compensation value of the first heating zone Z6 is determined, the compensation ratios may be changed depending on how much the difference values D1, D2, and D3 (see FIG. 7) are. For example, the greater the difference values D1, D2, and D3, the higher the compensation ratios, and the smaller the difference values D1, D2, and D3, the lower the compensation ratios.

In addition, when the second compensation value of the second heating zone Z5 is determined, reflection ratios in which the first compensation value affects the second compensation value may be changed depending on how much the difference values D1, D2, and D3 (see FIG. 7) in the first heating zone Z6 are. For example, the greater the difference values D1, D2, and D3, the higher the reflection ratios, and the smaller the difference values D1, D2, and D3, the lower the reflection ratios.

For example, in a case where the difference value of the first heating zone Z6 is 20° C., when the compensation ratio is 50%, the compensation value of the first heating zone Z6 may be determined as a value that may increase the temperature of the first heating zone by 10° C. Here, in a case where the difference value of the second heating zone Z5 is 18° C., when the compensation ratio of 50% and the reflection ratio of 50% are considered, the compensation value of the second heating zone Z5 may be determined as a value that may increase the temperature of the second heating zone by a temperature lower than 9° C. (for example, a value that may increase the temperature of the second heating zone by 7° C.) (in consideration of the reflection ratio) rather than a value that may increase the temperature of the second heating zone by 9° C.

Alternatively, in a case where the difference value of the first heating zone Z6 is 10° C., when the compensation ratio is 40%, the compensation value of the first heating zone Z6 may be determined as a value that may increase the temperature of the first heating zone by 4° C. Here, in a case where the difference value of the second heating zone Z5 is 8° C., when the compensation ratio of 40% and the reflection ratio of 40% are considered, the compensation value of the second heating zone Z5 may be determined as a value that may increase the temperature of the second heating zone by a temperature lower than 3.2° C. (for example, a value that may increase the temperature of the second heating zone by 2.4° C.) (in consideration of the reflection ratio) rather than a value that may increase the temperature of the second heating zone by 3.2° C.

Next, after the determined first compensation value and second compensation value are reflected, a plurality of sensed values are again received from the wafer-type temperature sensor, and the first temperature value of the first heating zone Z6 and the second temperature value of the second heating zone Z5 are re-generated. When the re-generated first temperature value and second temperature value are not suitable for the target value, the first compensation value and the second compensation value are re-calculated, and the re-calculated first compensation value and second compensation value are reflected. Such processes are repeated.

In a state in which the wafer-type temperature sensor is introduced into the substrate treating apparatus 100, the generating of the first temperature value and the second temperature value (S325), the determining of the first compensation value and the second compensation value (S327 and S329), and the re-generating of the first temperature value and the second temperature value may be continuously performed.

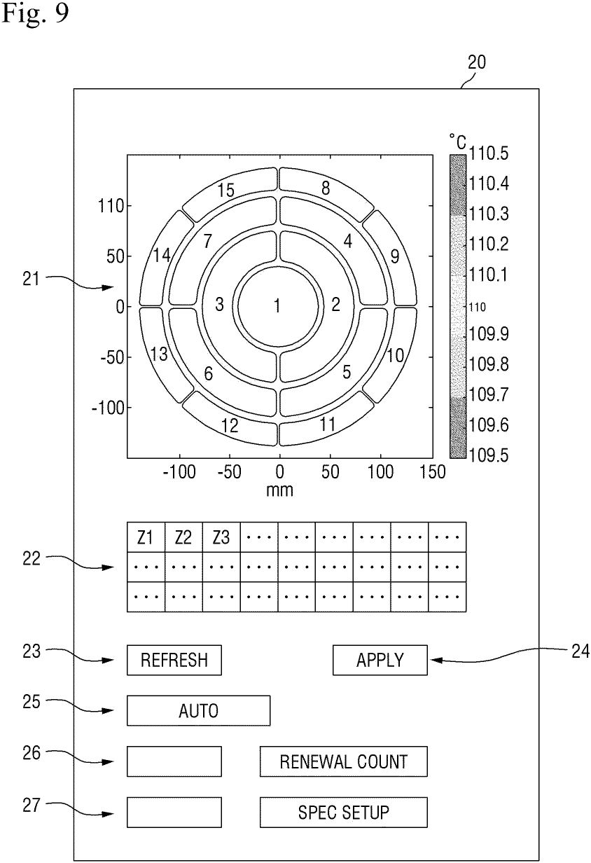

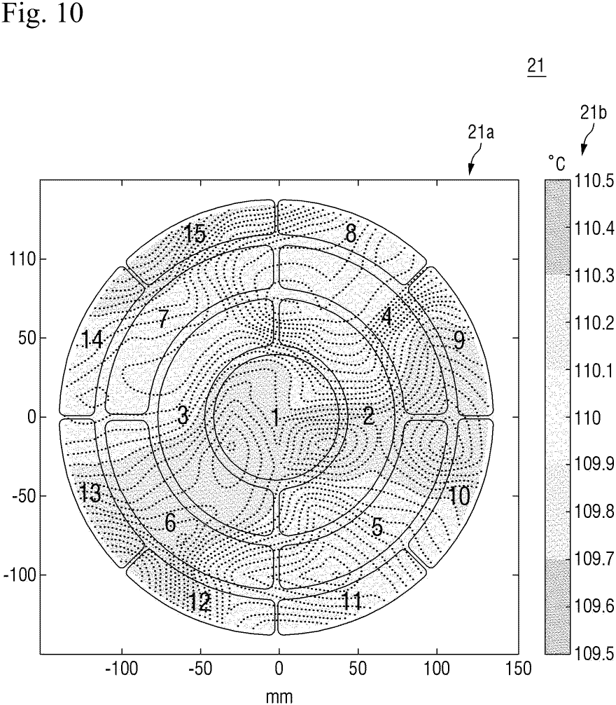

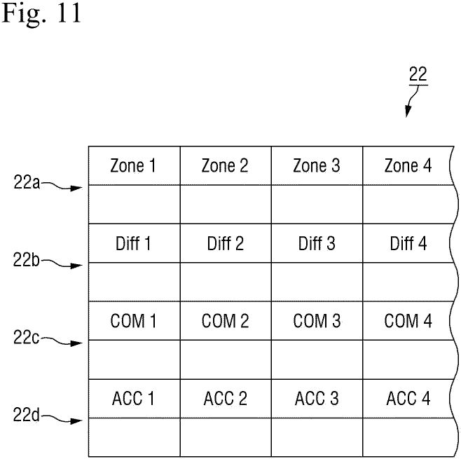

FIG. 9 is a graphical user interface (GUI) for describing software used in the process measurement method according to some exemplary embodiments of the present disclosure. FIG. 10 is a view for describing a temperature distribution viewer of FIG. 9. FIG. 11 is a view for describing a data table of FIG. 9.

First, referring to FIG. 9, a GUI 20 includes a temperature distribution viewer 21, a data table 22, a refresh button 23, an apply button 24, an auto-tuning button 25, an update number input blank 26, a specification setting input blank 27, and the like.

The temperature distribution viewer 21 overlaps and displays a temperature gradation (or a temperature map) with a plurality of heating zones. Since an operator may confirm the temperature gradation and the plurality of heating zones at the same time through the temperature distribution viewer 21, he or she may quickly decide a heating zone of which a temperature value deviates from a target value and quickly recognize a change process of the temperature distribution. When only the temperature gradation is displayed, the operator may not clearly know the corresponding heating zone. The heating zones illustrated in the temperature distribution viewer 21 may be displayed in the form of areas as illustrated in FIG. 10 or may be displayed in a form in which heating wires, thermoelectric elements, or the like, are arranged as illustrated in FIG. 2B.

The process measurement module 200 receives a plurality of sensed values from a plurality of sensors disposed in the wafer-type temperature sensor, and estimates a temperature gradation on the wafer based on the plurality of sensed values. The process measurement module 200 overlaps and displays the estimated temperature gradation with the plurality of heating zones.

Here, referring to FIG. 10, in a first area 21a of the temperature distribution viewer 21, the temperature gradation and the heating zones are simultaneously displayed, and the temperature gradation is displayed in colors, patterns, and the like. A second area 21b of the temperature distribution viewer 21 shows what temperature the colors, the patterns, and the like of the temperature gradation indicate.

In addition, the process measurement module 200 may calculate temperature values of each of the plurality of heating zones based on the plurality of sensed values that are received, and display the calculated temperature values in the form of the data table 22.

Here, referring to FIG. 11, the data table 22 may include a first portion 22a to a fourth portion 22d. Specifically, the first portion 22a indicates temperature values of each of a plurality of heating zones Zone1 to Zone4, and the second portion 22b indicates difference values (that is, differences between temperature values and a target value) of each of the plurality of heating zones Zone1 to Zone4. The third portion 22c indicates compensation values of each of the plurality of heating zones Zone1 to Zone4. In the third portion 22c, the compensation values may be displayed in the form of current values or may be displayed as temperatures corresponding to the current values. In addition, the fourth portion 22d indicates accumulated compensation values of each of the plurality of heating zones Zone1 to Zone4.

Referring again to FIG. 9, when a user clicks the refresh button 23, the data table 22 is refreshed.

When the user clicks the apply button 24, new compensation values are applied.

When the user clicks the auto-tuning button 25, a plurality of tuning steps (e.g., STEP1 to STEP4 in FIG. 7) are continuously performed within a preset range. For example, when the user inputs 3 in the update number input blank 26, the tuning step is continuously performed 3 times (i.e., STEP1 to STEP3 are continuously performed).

In addition, the user may input a reference standard deviation for deciding a stable condition in the specification setting input blank 27. That is, when the user inputs, for example, 0.03 in the specification setting input blank 27, if a calculated standard deviation is maintained below 0.03 for preset periods (e.g., 60 sampling periods), it may be decided as the stable condition.

In addition, although not illustrated separately, a manual input blank in which a compensation value may be additionally input by the operator may be further displayed. Through such manual input, the operator may finish tuning faster by reflecting his/her experience and skill.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. A process measurement method performed by a computing device, comprising:
receiving a plurality of sensed values from a plurality of sensors disposed in a wafer-type temperature sensor;
generating a first temperature value of a first heating zone based on the plurality of sensed values; and
determining a first compensation value based on a first difference value corresponding to a difference between the first temperature value and a target value,
wherein a first compensation ratio between the first difference value and the first compensation value when the first difference value is a first value is different from a second compensation ratio between the first difference value and the first compensation value when the first difference value is a second value.

2. The process measurement method of claim 1, wherein the first compensation value is a value compensated to be smaller than the first difference value.

3. The process measurement method of claim 1, wherein in the generating of the first temperature value,
the wafer-type temperature sensor includes a first sensor and a second sensor corresponding to the first heating zone, and the second sensor is disposed outside the first sensor in the first heating zone, and
the first temperature value is generated based on a first sensed value of the first sensor and a second sensed value of the second sensor.

4. The process measurement method of claim 3, wherein the first temperature value is a weighted average of the first sensed value and the second sensed value, and
a first weight given to the first sensed value is greater than a second weight given to the second sensed value.

5. The process measurement method of claim 3, wherein the first temperature value is a weighted average of the first sensed value and the second sensed value, and
a second weight given to the second sensed value is affected by a second temperature value of a second heating zone adjacent to the first heating zone.

6. The process measurement method of claim 1, further comprising receiving a plurality of sensed values again from the wafer-type temperature sensor and re-generating a first temperature value of the first heating zone, after reflecting the determined first compensation value.

7. The process measurement method of claim 6, wherein in a state in which the wafer-type temperature sensor is introduced into a substrate treating apparatus, the generating of the first temperature value of the first heating zone, the determining of the first compensation value, and the re-generating of the first temperature value of the first heating zone are continuously performed.

8. The process measurement method of claim 1, wherein when standard deviations of the plurality of sensed values received for preset periods are maintained below a preset value, the first temperature value is generated.

9. The process measurement method of claim 1, further comprising estimating a temperature gradation based on the plurality of sensed values received from the wafer-type temperature sensor and overlapping and displaying the temperature gradation with a plurality of heating zones.

10. A process measurement method performed by a computing device, comprising:
receiving a plurality of sensed values from a plurality of sensors disposed in a wafer-type temperature sensor;
generating a first temperature value of a first heating zone and a second temperature value of a second heating zone adjacent to the first heating zone based on the plurality of sensed values;
determining a first compensation value based on a first difference value corresponding to a difference between the first temperature value and a target value; and
determining a second compensation value based on a second difference value corresponding to a difference between the second temperature value and the target value and the first compensation value.

11. The process measurement method of claim 10, wherein the first difference value is greater than the second difference value.

12. The process measurement method of claim 10, wherein a first compensation ratio between the first difference value and the first compensation value when the first difference value is a first value is different from a second compensation ratio between the first difference value and the first compensation value when the first difference value is a second value.

13. The process measurement method of claim 10, wherein a first reflection ratio in which the first compensation value affects the second compensation value when the first difference value is a first value is different from a second reflection ratio in which the first compensation value affects the second compensation value when the first difference value is a second value.

14. The process measurement method of claim 10, wherein the first compensation value is not affected by the second compensation value.

15. The process measurement method of claim 10, wherein in the generating of the first temperature value,
the wafer-type temperature sensor includes a first sensor and a second sensor corresponding to the first heating zone, and the second sensor is disposed outside the first sensor in the first heating zone, and
the first temperature value is a weighted average of a first sensed value of the first sensor and a second sensed value of the second sensor, and a first weight given to the first sensed value is greater than a second weight given to the second sensed value.

16. The process measurement method of claim 10, further comprising receiving a plurality of sensed values again from the wafer-type temperature sensor and re-generating a first temperature value of the first heating zone and a second temperature sensor of the second heating zone, after reflecting the determined first compensation value and second compensation value,
wherein in a state in which the wafer-type temperature sensor is introduced into a substrate treating apparatus, the generating of the first temperature value and the second temperature value, the determining of the first compensation value and the second temperature value, and the re-generating of the first temperature value and the second temperature value are continuously performed.

17. A process measurement method performed by a computing device, comprising:
receiving a plurality of sensed values from a plurality of sensors disposed in a wafer-type temperature sensor;
estimating a temperature gradation based on the plurality of sensed values;
overlapping and displaying the estimated temperature gradation with a plurality of heating zones; and
calculating and displaying temperature values of each of the plurality of heating zones based on the plurality of sensed values.

18. The process measurement method of claim 17, further comprising determining and displaying compensation values of each of the plurality of heating zones based on a plurality of difference values corresponding to differences between the temperature values of each of the plurality of heating zones and a target value.

19. The process measurement method of claim 18, further comprising displaying accumulated compensation values of each of the plurality of heating zones together.

20. The process measurement method of claim 18, further comprising displaying a manual input blank in which a compensation value is additionally input by an operator.
